(19) United States
(12) Patent Application Publication
(10) Pub. No.: US 2021/0356940 A1
(43) Pub. Date: Nov. 18, 2021

(54) DETERMINING A LASER-ENGRAVING PROCESS FOR A TARGETED SURFACE GEOMETRY

(71) Applicant: Standex International Corporation, Salem, NH (US)

(72) Inventors: Francesco IORIO, Toronto (CA); Ian Ross AMELINE, Toronto (CA); Tasso Anastasios KARKANIS, Toronto (CA); Michael Wenhan TAO, Toronto (CA); Massimiliano MORUZZI, Rockford, IL (US); Aaron Michael SZYMANSKI, Toronto (CA)

(21) Appl. No.: 17/317,622

(22) Filed: May 11, 2021

Related U.S. Application Data
(60) Provisional application No. 63/023,778, filed on May 12, 2020.

(51) Int. Cl. G05B 19/4155; B23K 26/362; B23K 26/0622

(52) U.S. Cl. CPC G05B 19/4155; G05B 2219/45163; B23K 26/0622; B23K 26/362

(57) ABSTRACT

A computer-implemented method determining one or more parameter values for a laser-engraving process, the method comprising: executing a laser pulse model on a computer-simulated surface to generate a first surface geometry on the computer-simulated surface, wherein the laser pulse model is based on a first set of values for a set of parameters; determining a quality score for the first surface geometry; based on the quality score, performing a global optimization process to generate a second set of values for the set of parameters; and modifying the laser pulse model based on the second set of values to generate a modified laser pulse model.

### CROSS-REFERENCE TO RELATED APPLICATIONS

This application claims priority benefit of the United States Provisional patent application titled, “LASER ENGRAVING SIMULATION WITH ACCOMPANYING STRATEGY GENERATION AND OPTIMIZATION,” filed on May 12, 2020 and having Ser. No. 63/023,778. The subject matter of this related application is hereby incorporated herein by reference.

### BACKGROUND

### Field of the Various Embodiments

The various embodiments relate generally to laser engraving and computer science, and, more specifically, to determining a laser-engraving process for a targeted surface geometry.

### Description of the Related Art

Laser engraving is a technique used to obtain a specific geometric pattern on a surface of a material via a focused laser beam. By injecting energy onto the surface using a focused laser beam, discrete locations on the surface are heated, and portions of the material are displaced and/or vaporized. Patterned surface geometries formed in this way can render a desired aesthetic texture on the surface and/or create geometric microstructures that alter the material properties of the material. Laser engraving can be implemented on a wide variety of materials and, therefore, has many useful applications. However, current approaches for developing new laser-engraving processes are very limited.

To obtain a desired surface geometry via laser engraving on a given material surface, many factors need to be accurately determined. Those factors include, without limitation, the number of passes made by a laser over the surface, the specific values of various laser process parameters used to configure the laser for each pass, and the material makeup and initial geometry of the surface. In addition, to balance the trade-off between the quality of a resulting surface geometry and the speed of the laser-engraving process, these factors usually need to be optimized. The process of determining and optimizing these various factors is time-consuming, labor intensive, and prone to error.

Currently, the process of selecting an appropriate laser engraving strategy that accounts for the above factors is manual and based on trial and error. For example, for a targeted surface geometry, a series of laser-engraving experiments is first performed using a laser engraving machine on multiple different surfaces to produce a variety of engraved surfaces. Manual analysis of the resulting engraved surfaces, for example, via an optical or laser surface scanner, can then be used to assess whether any of the laser-engraving experiments produces an engraved surface having surface geometry that adequately approximates the targeted surface geometry. Drawbacks of this type of conventional approach include the time and labor required to perform the laser-engraving experiments and follow-up analysis and the risk that none of the laser-engraving experiments actually produces an engraved surface having surface geometry that adequately approximates the target surface geometry.

In many applications, when modifying a physical process, computer simulations of the physical process are often employed to minimize or even eliminate the need for a trial-and-error experimental approach. With laser-engraving, however, conventional computer simulations have limited utility. In particular, accurately characterizing how a series of laser pulses directed onto a given surface alters the geometry of that surface is a highly complex thermo-mechanical problem. To properly model this type of problem, several factors must be considered, including, and without limitation, the time-transient nature of the energy distribution of a laser pulse, the phase-state change (i.e., melting and/or vaporizing) of the portions of the surface that are treated, the thermal and mechanical effects within the surface associated with heating and cooling, and the secondary effects of the melt pool. To generate accurate results for such a problem using a finite-element method, high-resolution discretization in both space and time is required. Consequently, an accurate simulation of the thermo-mechanical effects of a single laser pulse on a particular surface can take minutes to hours to execute. Extending that approach to the millions or billions of laser pulses employed in generating a single simulated surface associated with a single set of process parameters is entirely impracticable. Performing such a procedure for different combinations of process parameters to determine an optimal laser-engraving solution is even more impracticable.

As the foregoing illustrates, what is needed in the art are more effective ways to determine a laser-engraving process to generate a targeted surface geometry.

### SUMMARY

A computer-implemented method for determining one or more parameter values for a laser-engraving process, the method comprising: executing a laser pulse model on a computer-simulated surface to generate a first surface geometry on the computer-simulated surface, wherein the laser pulse model is based on a first set of values for a set of parameters; determining a quality score for the first surface geometry; based on the quality score, performing a global optimization process to generate a second set of values for the set of parameters; and modifying the laser pulse model based on the second set of values to generate a modified laser pulse model.

At least one technical advantage of the disclosed techniques relative to the prior art is that the disclosed techniques enable laser-engraving process parameters to be accurately determined for a target surface geometry. Accordingly, with the disclosed techniques, the time and effort required to perform a large number of real-world laser-engraving experiments and analyses to identify a laser-engraving solution that generates the target surface geometry can be substantially avoided. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a parameter-generation system that is configured to implement one or more aspects of the various embodiments.

FIG. 2A schematically illustrates a plan view of a target surface geometry, according to various embodiments.

FIG. 2B schematically illustrates a cross-sectional view of the target surface geometry of FIG. 2A, according to various embodiments.

FIG. 3A schematically illustrates a plan view of laser-raster lines included in a first phase of a laser-engraving process for generating a surface geometry, according to various embodiments.

FIG. 3B schematically illustrates a plan view of laser-raster lines included in a second phase of a laser-engraving process for generating a surface geometry, according to an embodiment.

FIG. 3C schematically illustrates a plan view of laser-raster lines included in a third phase of a laser-engraving process for generating a surface geometry, according to an embodiment.

FIG. 3D schematically illustrates a cross-sectional view of a surface geometry, according to various embodiments.

FIG. 4 sets forth a flowchart of method steps for determining the parameter values for a laser-engraving process, according to various embodiments.

FIG. 5 is a block diagram of a computing device configured to implement one or more aspects of the various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skill in the art that the inventive concepts may be practiced without one or more of these specific details.

### System Overview

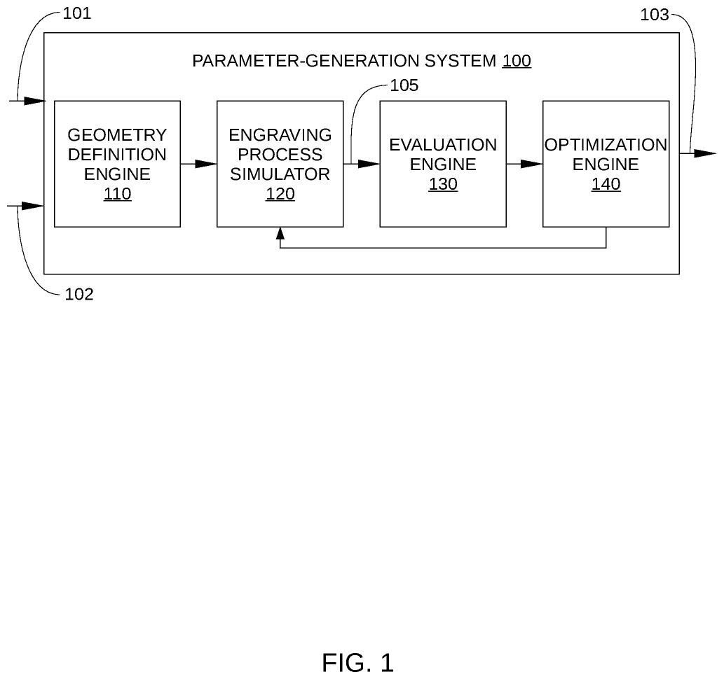

FIG. 1 illustrates a parameter-generation system 100 that is configured to implement one or more aspects of the various embodiments. Parameter-generation system 100 includes a geometry definition engine 110, an engraving process simulator 120, an evaluation engine 130, and an optimization engine 140. Parameter-generation system 100 is configured to determine a specific laser-engraving process 103 that is configured to form or produce a target surface geometry 101 on a workpiece surface (hereinafter a “surface”). In some embodiments, in addition to target surface geometry 101, parameter-generation system 100 generates laser-engraving process 103 based on a set of values 102 for one or more parameters for the surface being processed. In such embodiments, parameters for the surface associated with the set of values 102 may include specific material properties of the surface (e.g., melting point, reflectivity, heat capacity, and the like).

Target surface geometry 101 includes geometrical information describing a specific surface geometry to be generated via a laser-engraving process. Thus, a goal of parameter-generation system 100 is to determine parameters for a laser-engraving process that generates a surface that is similar or identical to target surface geometry 101. Generally, target surface geometry 101 includes three-dimensional (3D) information for such a surface geometry. In some embodiments, target surface geometry 101 includes such 3D information as a height map, which is a single-channel image of a given resolution. In such embodiments, each pixel of the height map corresponds to a digital elevation or depth of target surface geometry 101 at a specific location on the surface. In other embodiments, target surface geometry 101 can be in any other suitable format that conveys 3D information regarding the configuration of a target surface geometry. For example, in some embodiments, target surface geometry 101 includes a digital elevation map or a geometric construct formed via polygons.

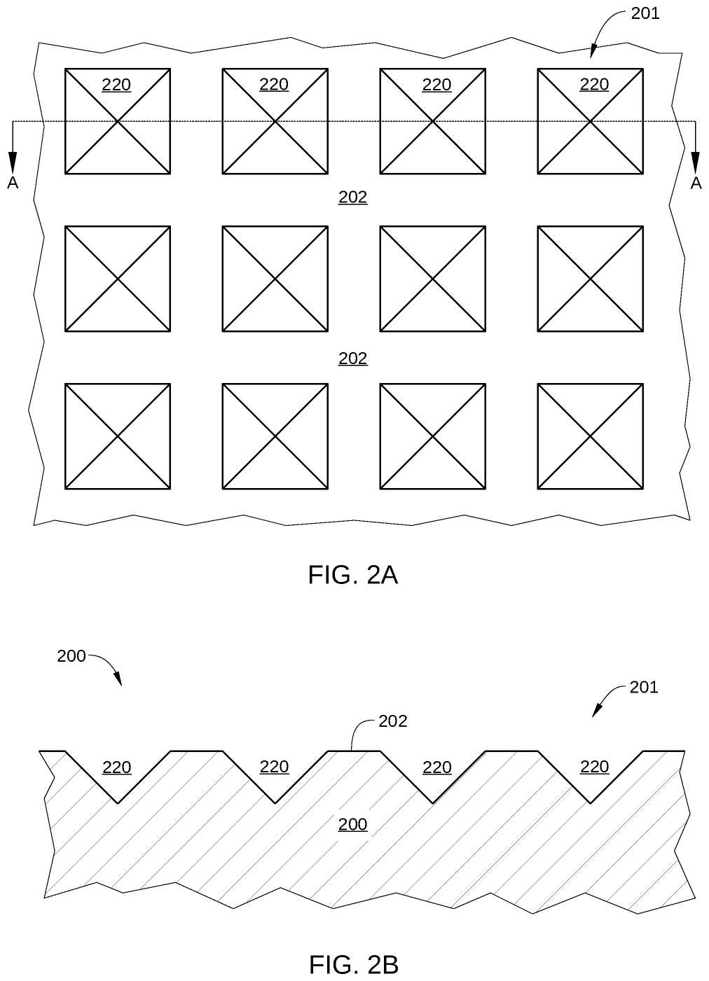

In the context of laser-engraving, target surface geometry 101 references a 3D surface having small-scale features that, taken together, form a specific texture on a workpiece surface. For example, in some embodiments, the specific texture can be configured to produce a desired aesthetic texture on a workpiece surface, provide a surface that has certain mechanical properties, and/or include geometric microstructures that alter the material properties of the material of the workpiece surface. One embodiment of a target surface geometry 101 is described below in conjunction with FIGS. 2A and 2B.

FIG. 2A schematically illustrates a plan view of a target surface geometry 201, according to various embodiments, and FIG. 2B schematically illustrates a cross-sectional view of target surface geometry 201 taken at section A-A, according to various embodiments. Target surface geometry 201 includes a plurality of inverted pyramid cavities 220 that are formed below a top surface 202 of a workpiece 200. Inverted pyramid cavities 220 are formed by the removal of material from workpiece 200, via the injection of heat in precise locations on top surface 202, and in some embodiments in precise locations on one or more subsequently exposed surfaces of workpiece 200. Specifically, a series of individual laser pulses are directed to surface 202 during a specified laser-engraving process. In such processes, multiple laser passes are performed, since laser-engraving is generally limited in how much material can be removed from surface 202 in a single pass. For example, in embodiments in which workpiece 200 is a metallic material, the quantity of material that can be removed is on the order of a few microns per pass. In the embodiment shown in FIGS. 2A and 2B, inverted pyramid cavities 220 are on the order of ten or more microns, and therefore a specific laser-engraving process that can form inverted pyramid cavities 220 necessarily includes multiple laser passes over surface 202.

In the embodiment illustrated in FIGS. 2A and 2B, target surface geometry 201 includes portions of surface 202, which is an initial surface of workpiece 200. In other embodiments, target surface geometry 201 may have a configuration that precludes portions of surface 202 remaining after the specific laser-engraving process is performed. Further, the cavities formed in surface 202 via the specific laser-engraving process can be any technically feasible shape, depth, and/or cross-section. For example, in some embodiments, some or all of such cavities can be spherical in cross-section, rectangular in cross-section, etc. Additionally or alternatively, in some embodiments, cavities formed in surface 202 may not be identical in size, shape, and/or depth.

Returning to FIG. 1, laser-engraving process 103 is the output of parameter-generation system 100. As such, laser-engraving process 103 includes values for the laser-engraving parameters of a specific laser engraving process that produces a surface geometry on a surface that approximates the configuration of target surface geometry 101 to a suitable level of precision. In some embodiments, the process parameters of the laser-engraving process include parameters associated with the laser source, and, in some embodiments, parameters associated with the surface being processed. Further, in some embodiments, the process parameters of the laser-engraving process may include a number of laser passes (referred to herein as “phases”) included in the laser-engraving process. Thus, in various embodiments, parameter-generation system 100 can generate a suitable combination of different values of parameters for a laser-engraving process (represented by laser-engraving process 103 in FIG. 1) based on a specific laser-engraved surface, such as a specific target surface geometry 101.

In some embodiments, parameters for the laser source include laser power, pulse frequency, and engraving speed (e.g., the linear speed at which a laser spot moves across the surface being processed), among others. Additionally or alternatively, in some embodiments, parameters for the laser source include one or more other parameters for the movement of the laser beam with respect to the surface, such as one or more of laser incidence angle with respect to the surface being processed, and/or laser trajectory. In some embodiments, laser incidence angle and laser trajectory are functions of the geometry of a particular laser-engraving system and mirror configuration that are employed to move a laser beam over the surface. Additionally or alternatively, in some embodiments, parameters for the laser source include one or more parameters associated with a laser spot size, a frequency of the laser source, and/or the like.

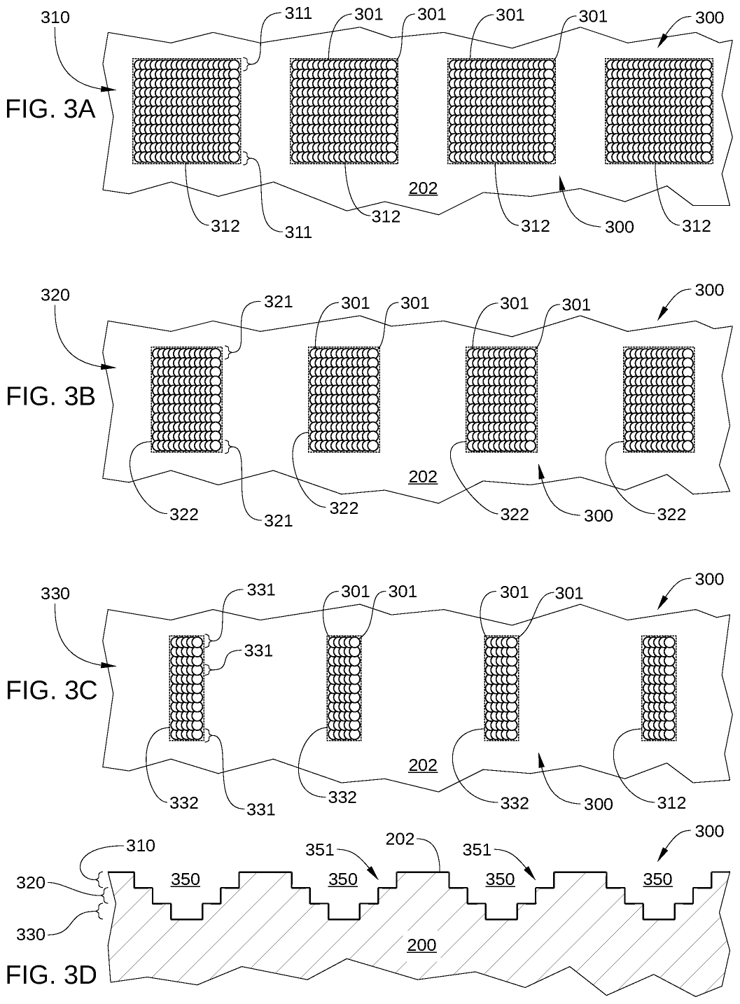

Geometry definition engine 110 is configured to determine a location on the surface for each laser pulse included in the plurality of laser pulses that make up a laser-engraving process. Geometry definition engine 110 is configured to determine such locations based at least in part on target surface geometry 101. In some embodiments, geometry definition engine 110 determines such locations by determining a location for one or more laser-raster lines, where each of the one or more laser-raster lines comprises a sequence of laser pulses of the laser-engraving process. Furthermore, in embodiments in which a laser-engraving process includes multiple phases, geometry definition engine 110 determines locations for each laser pulse in each phase of the laser-engraving process. In such embodiments, geometry definition engine 110 also determines the configuration of each phase, where each phase effectuates material removal from a different layer or depth of the workpiece. For example, in such embodiments, geometry definition engine 110 determines a location of one or more laser-raster lines for each of the multiple phases. One such embodiment is described below in conjunction with FIGS. 3A-3D.

FIG. 3A schematically illustrates a plan view of laser-raster lines 311 included in a first phase 310 of a laser-engraving process for generating a surface geometry 300, according to various embodiments. Each of laser-raster lines 311 is formed by a series of laser pulses that are directed to surface 202 at a circular laser pulse location 301. In some embodiments, each laser pulse location 301 associated with a laser-raster line 311 is located to overlap a significant portion of one or more of the other laser pulse locations 301 associated with the laser-raster line 311. Because each laser pulse location 301 results in a crater of material being removed from surface 202, a series of laser pulse locations 301 results in a groove or trough of material being removed from surface 202. In the embodiment illustrated in FIG. 3A, each laser-raster line 311 is positioned to touch or slightly overlap adjacent laser-raster lines 311. As a result, groups of overlapping or touching laser-raster lines 311 form regions 312 (indicated by dashed lines) in which material is removed from a workpiece in the current phase of the laser-engraving process. In the embodiments illustrated in FIG. 3A, regions 312 each have a square configuration that corresponds to the first-phase portion of an inverted pyramid cavity 220 (such as that shown in FIGS. 2A and 2B) of surface geometry 300.

FIG. 3B schematically illustrates a plan view of laser-raster lines 321 included in a second phase 320 of a laser-engraving process for generating surface geometry 300, according to various embodiments. As shown, each of laser-raster lines 321 is formed by a series of laser pulses that are directed to surface 202 at a circular laser pulse location 301. In some embodiments, each laser pulse location 301 associated with a laser-raster line 321 is located to overlap a significant portion of one or more of the other laser pulse locations 301 associated with the laser-raster line 321. In the embodiment illustrated in FIG. 3B, laser-raster lines 321 form regions 322 (indicated by dashed lines) in which material is removed from a workpiece in the current phase of the laser-engraving process. In the embodiments illustrated in FIG. 3B, regions 322 each have a rectangular configuration that corresponds to the second-phase portion of surface geometry 300.

FIG. 3C schematically illustrates a plan view of laser-raster lines 331 included in a third phase 330 of a laser-engraving process for generating surface geometry 300, according to various embodiments. As shown, each of laser-raster lines 331 is formed by a series of laser pulses that are directed to surface 202 at a circular laser pulse location 301. In some embodiments, each laser pulse location 301 associated with a laser-raster line 331 is located to overlap a significant portion of one or more of the other laser pulse locations 301 associated with the laser-raster line 331. In the embodiment illustrated in FIG. 3C, laser-raster lines 331 form regions 332 (indicated by dashed lines) in which material is removed from a workpiece in the current phase of the laser-engraving process. In the embodiments illustrated in FIG. 3C, regions 332 each have a rectangular configuration that corresponds to the third-phase portion of surface geometry 300.

FIG. 3D schematically illustrates a cross-sectional view of surface geometry 300, according to various embodiments. Surface geometry 300 is formed to approximate an inverted pyramid shape (such as that shown in FIGS. 2A and 2B) via three phases of a laser-engraving process, e.g., first phase 310, second phase 320, and third phase 330). As shown in FIG. 3D, each phase of the laser-engraving process is associated with an isocontour of the target surface geometry, where each isocontour corresponds to material removal at a different elevation of the target surface geometry. Because a discrete number of phases is employed to generate inverted pyramid cavities 350 of surface geometry 300, the sloping edges of such cavities are approximated with a “stair-step” pattern 351, where each step corresponds to a different phase of the laser-engraving process. In the embodiment illustrated in FIG. 3D, the laser-engraving process includes three such phases. As a result, the stair-step pattern is relatively pronounced, and aliasing of the sloping edges is evident. In other embodiments, the laser-engraving process includes a larger number of such phases, for example 10, 20, 30, or more. In such embodiments, stair-step pattern 351 is much less pronounced and aliasing of the sloping edges of surface geometry 300 is less evident.

In the embodiment illustrated in FIG. 3D, the laser-engraving process includes three phases in which a uniform thickness of material is removed in each phase. In other embodiments, a thickness of material removed from a surface can be variable, depending on the phase of the laser-engraving process. For example, in some embodiments, to reduce aliasing, less material is removed in phases of the laser-engraving process associated with a portion of a target surface geometry that has a lower angle, i.e., an angle closer to being parallel with surface 202. By contrast, in such embodiments, more material is removed in phases of the laser-engraving process associated with a portion of the target surface that has a higher angle, i.e., an angle that is closer to being perpendicular to surface 202.

Returning to FIG. 1, engraving process simulator 120 is configured to generate surface geometry 105 on a simulated surface that accurately represents a target surface geometry, such as target surface geometry 101. In some embodiments, engraving process simulator 120 simulates, on a pulse-by-pulse basis, the effects of a specific laser-engraving process on a surface. In such embodiments, engraving process simulator 120 applies the effects of each laser pulse of a specific laser-engraving process based on the laser-pulse locations determined by geometry definition engine 110 to generate surface geometry 105 on the computer-simulated surface. In some embodiments, the specific laser-engraving process is defined by or otherwise based on a set of values for various laser-engraving parameters, such as one or more parameters associated with the laser source, one or more parameters associated with the surface being processed, and/or a number of phases included in the laser-engraving process. By determining the effect on a computer-simulated surface of each individual laser pulse of a particular laser-engraving process, engraving process simulator 120 generates a simulated surface (e.g., surface geometry 105) that accurately represents an actual surface that has undergone the particular laser-engraving process. Thus, based on the set of values for the process parameters of a laser-engraving process, a resultant surface geometry 105 can be determined for a particular laser-engraving process without physically performing the laser-engraving process with an actual laser-engraving system.

Engraving process simulator 120 may include any technically feasible simulation algorithm or algorithms that can determine the effect of each laser pulse of a laser-engraving process on a surface. In some embodiments, engraving process simulator 120 includes a finite-element analysis software application that determines such effects. Generally, finite-element analysis that accurately models the complex thermomechanical effects of material displacement and phase changes associated with laser heating and subsequent cooling is too cumbersome to be employed for each laser pulse in a typical laser-engraving process. Thus, in some embodiments, engraving process simulator 120 includes a reduced-order laser-engraving model that includes a geometric model of the effect that a particular laser pulse has on the surface. One such model is described in greater detail in United States Non-Provisional patent application titled, “Determining a Laser-Engraved Surface Using a Reduced-Order Model,” filed on May 11, 2021 and having Ser. No. 17/317,149, the subject matter of which is hereby incorporated herein by reference in its entirety.

Evaluation engine 130 is configured to evaluate surface geometry 105 generated by engraving process simulator 120, for example via a quality score. In some embodiments, evaluation engine 130 generates the quality score for surface geometry 105 based on multiple values, where each value is associated with a different attribute of surface geometry 105. In such embodiments, each attribute enables the quality of surface geometry 105 to be quantified with respect to a different objective factor. For example, in some embodiments, the quality score generated by evaluation engine 130 includes a value associated with a surface quality of surface geometry 105, a value associated with a surface roughness of surface geometry 105, and/or a value associated with an engraving time of surface geometry 105. In such embodiments, each value may be weighted differently for each instance of laser-engraving process 103.

In some embodiments, the value associated with the surface quality of surface geometry 105 can indicate how closely surface geometry 105 matches target surface geometry 101. For example, in such embodiments, a surface profile associated with and/or extracted from surface geometry 105 can be compared to a surface profile associated with or extracted from target surface geometry 101. Thus, in such embodiments, a quantitative comparison is performed that determines a surface quality score of surface geometry 105 relative to target surface geometry 101.

In some embodiments, the value associated with the surface roughness of surface geometry 105 can indicate how closely a surface roughness of surface geometry 105 matches a surface roughness of target surface geometry 101. Thus, in such embodiments, a quantitative comparison is performed that determines a surface roughness score of surface geometry 105 relative to target surface geometry 101. In such embodiments, any suitable surface roughness calculation may be employed to determine a surface roughness of surface geometry 105 and/or target surface geometry 101, such as a root-mean-square (RMS) roughness method, an Ra (arithmetic average roughness) method, and the like. Alternatively or additionally, in such embodiments, multiple surface roughness calculations may be employed to determine the surface roughness of surface geometry 105 and/or target surface geometry 101.

In some embodiments, the value associated with the engraving time of surface geometry 105 can indicate a time required for a particular laser-engraving system to generate surface geometry 105 on a surface. In such embodiments, the time required may be based on how many phases the laser-engraving process includes, the physical capabilities of the particular laser-engraving system to perform the laser-engraving process (such as engraving speed, mirror-repositioning time between laser-raster lines, and the like), and the number of laser-raster lines included in each phase.

It is noted that one or more of the values included in the quality score generated by evaluation engine 130 can be in conflict with each other. For example, more phases (laser passes) in a laser-engraving process are generally required to reduce aliasing and thereby improve the how closely surface geometry 105 matches target surface geometry 101. However, more layers require more engraving time, which increases the value associated with the engraving time of surface geometry 105. According to various embodiments, a multi-objective optimization process (performed by optimization engine 140) is performed in parameter-generation system 100 to determine an instance of laser-engraving process 103 based on the above-described quality score. As a result of the multi-objective optimization process, the laser-engraving process 103 so determined has an improved performance with respect to each of the multiple attributes of surface geometry 105 that is associated with a value included in the quality score for surface geometry 105.

Optimization engine 140 is configured to select values for the parameters of the laser-engraving process that improve the quality score determined by evaluation engine 130. Because multiple objectives can be associated with how well a particular surface geometry 105 (such as surface quality, surface roughness, and/or engraving time), optimization engine 140 typically performs a multi-objective optimization process to determine new values for the parameters of the laser-engraving process. Any suitable optimization algorithm capable of a multi-objective search in a solution space can be employed by optimization engine 140.

In many embodiments, a laser-engraving process includes multiple parameters that can have interacting effects. For example, higher laser power can remove material faster from a surface, but have more explosive vaporization of such material, which can significantly increase surface roughness of the surface. In another example, lower engraving speed can create more overlap of adjacent laser pulses and more melting, which can reduce rugosities on the surface and thereby reduce surface roughness of the surface. In light of the above, in some embodiments optimization engine 140 includes a global optimization algorithm, to facilitate determination of a global optimum solution with respect to the multiple objectives that are associated with a particular surface geometry 105 and how well that particular surface geometry 105 matches target surface geometry 101.

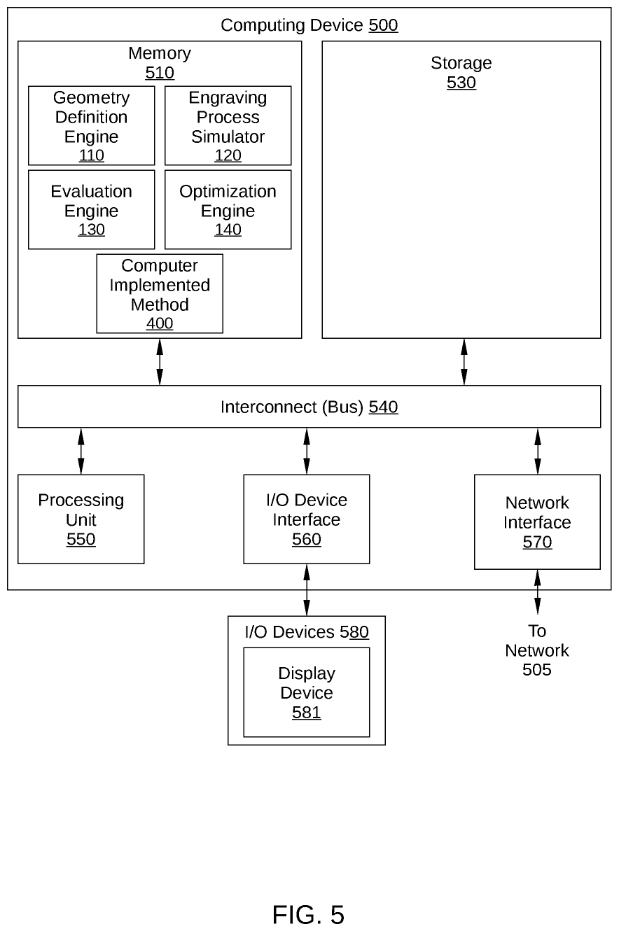

In the embodiments described above, geometry definition engine 110, engraving process simulator 120, evaluation engine 130, and optimization engine 140 are depicted as separate software applications or algorithms. In other embodiments, two or more of geometry definition engine 110, engraving process simulator 120, evaluation engine 130, and/or optimization engine 140 can be implemented as a single software application or algorithm via a single computing device or via multiple computing devices. An embodiment of one such computing device is described below in conjunction with FIG. 5.

### Determining the Parameter Values for a Laser-Engraving Process

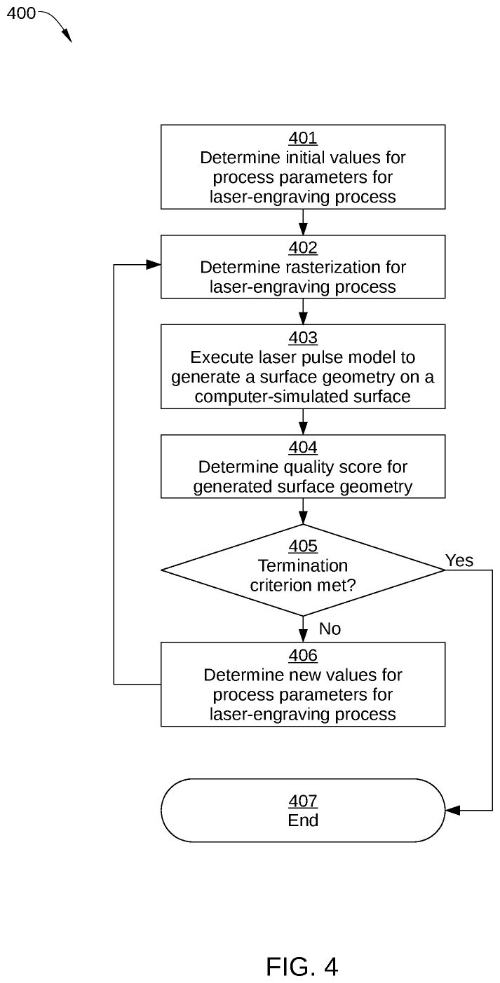

FIG. 4 sets forth a flowchart of method steps for determining values for a set of parameters associated with a laser-engraving process, according to various embodiments. In the various embodiments, the laser-engraving process generates a target surface geometry. Although the method steps are described in conjunction with the system of FIGS. 1-3D, persons skilled in the art will understand that any system configured to perform the method steps, in any order, is within the scope of the embodiments.

As shown, a computer-implemented method 400 begins at step 401, where parameter-generation system 100 determines initial values for process parameters for a particular laser-engraving process to be determined. The particular laser-engraving process to be determined is laser-engraving process 103, which is a laser-engraving process that can generate a surface geometry 105 that satisfactorily matches one or more attributes of target surface geometry 101. In some embodiments, the initial values for some or all process parameters of the laser-engraving process are received in conjunction with or are based on target surface geometry 101. For example, based on one or more attributes of target surface geometry, such as feature depth, orientation of angles surface, etc., parameter-generation system 100 may have a default set of initial values for some or all parameters of the laser-engraving process.

In step 402, parameter-generation system 100 determines rasterization for the laser-engraving process being determined, for example via geometry definition engine 110. In some embodiments, as part of rasterization, geometry definition engine 110 determines the locations of the laser-raster lines included in each layer of the laser-engraving process. In some embodiments, the location of each laser pulse of the laser-engraving process is also determined in step 402. Alternatively, in some embodiments, the location of each laser pulse is determined via engraving process simulator 120.

In step 403, parameter-generation system 100 executes a laser pulse model to generate surface geometry 105 on a computer-simulated surface. In some embodiments, the laser pulse model is included in engraving process simulator 120.

In step 404, parameter-generation system 100 determines a quality score for the instance of surface geometry 105 generated in step 403. In some embodiments, the quality score includes multiple values, where each value is associated with a different attribute of surface geometry 105.

In step 405, parameter-generation system 100 determines whether a termination criterion has been met by the current instance of surface geometry 105. If no, computer-implemented method 400 proceeds to step 406; if yes, computer-implemented method 400 proceeds to step 407 and terminates. In some embodiments, the termination criterion can be a threshold value of the quality score for surface geometry 105 or a threshold value for a change in quality score compared to a previous value of the quality score. In some embodiments, the termination criterion can be a number of iterations that steps 402-405 have been performed for a particular target surface geometry 101. In some embodiments, the termination criterion can be a threshold time interval during which iterations of steps 402-405 have been performed for a particular target surface geometry 101.

In step 406, parameter-generation system 100 determines new values for the process parameters for the laser-engraving process being determined, for example via optimization engine 140. In some embodiments, optimization engine 140 generates the new values for the process parameters based at least in part on the quality score determined in step 404.

In step 407, parameter-generation system 100 terminates computer-implemented method 400. In some embodiments, the instance of laser-engraving process 103 that has the best quality score is determined to be the final version.

### Exemplary Computing Device

FIG. 5 is a block diagram of a computing device 500 configured to implement one or more aspects of the various embodiments. Thus, computing device 500 can be a computing device associated with parameter-generation system 100. Computing device 500 may be a desktop computer, a laptop computer, a tablet computer, or any other type of computing device configured to receive input, process data, generate control signals, and display images. Computing device 500 is configured to run geometry definition engine 110, engraving process simulator 120, evaluation engine 130, optimization engine 140, computer-implemented method 400, and/or other suitable software applications, which can reside in a memory 510. It is noted that the computing device described herein is illustrative and that any other technically feasible configurations fall within the scope of the present disclosure.

As shown, computing device 500 includes, without limitation, an interconnect (bus) 540 that connects a processing unit 550, an input/output (I/O) device interface 560 coupled to input/output (I/O) devices 580, memory 510, a storage 530, and a network interface 570. Processing unit 550 may be any suitable processor implemented as a central processing unit (CPU), a graphics processing unit (GPU), an application-specific integrated circuit (ASIC), a field programmable gate array (FPGA), any other type of processing unit, or a combination of different processing units, such as a CPU configured to operate in conjunction with a GPU. In general, processing unit 550 may be any technically feasible hardware unit capable of processing data and/or executing software applications, including geometry definition engine 110, engraving process simulator 120, evaluation engine 130, optimization engine 140, and/or computer-implemented method 400. Further, in the context of this disclosure, the computing elements shown in computing device 500 may correspond to a physical computing system (e.g., a system in a data center) or may be a virtual computing instance executing within a computing cloud.

I/O devices 580 may include devices capable of providing input, such as a keyboard, a mouse, a touch-sensitive screen, and so forth, as well as devices capable of providing output, such as a display device 581. Additionally, I/O devices 580 may include devices capable of both receiving input and providing output, such as a touchscreen, a universal serial bus (USB) port, and so forth. I/O devices 580 may be configured to receive various types of input from an end-user of computing device 500, and to also provide various types of output to the end-user of computing device 500, such as one or more graphical user interfaces (GUI), displayed digital images, and/or digital videos. In some embodiments, one or more of I/O devices 580 are configured to couple computing device 500 to a network 505.

Memory 510 may include a random access memory (RAM) module, a flash memory unit, or any other type of memory unit or combination thereof. Processing unit 550, I/O device interface 560, and network interface 570 are configured to read data from and write data to memory 510. Memory 510 includes various software programs that can be executed by processor 550 and application data associated with said software programs, including geometry definition engine 110, engraving process simulator 120, evaluation engine 130, optimization engine 140, and/or computer-implemented method 400.

In sum, the various embodiments described herein provide techniques for the determination of values for the process parameters of a specific laser-engraving process to generate a target laser-engraved surface. In the embodiments, a laser pulse model is iteratively employed to generate a candidate surface geometry, the candidate surface geometry is evaluated with respect to the target laser-engraved surface, and new values for the process parameters are generated via a multi-objective optimization process.

At least one technical advantage of the disclosed techniques relative to the prior art is that the disclosed techniques enable laser-engraving process parameters to be accurately determined for a target surface geometry. Accordingly, with the disclosed techniques, the time and effort required to perform a large number of real-world laser-engraving experiments and analyses to identify a laser-engraving solution that generates the target surface geometry can be substantially avoided. These technical advantages provide one or more technological advancements over prior art approaches.

1. In some embodiments, a computer-implemented method for determining one or more parameter values for a laser-engraving process, the method comprising: executing a laser pulse model on a computer-simulated surface to generate a first surface geometry on the computer-simulated surface, wherein the laser pulse model is based on a first set of values for a set of parameters; determining a quality score for the first surface geometry; based on the quality score, performing a global optimization process to generate a second set of values for the set of parameters; and modifying the laser pulse model based on the second set of values to generate a modified laser pulse model.

2. The computer-implemented method of clause 1, wherein an objective function of the global optimization process is based on a plurality of objective factors associated with the first surface geometry, and each objective factor included in the plurality of objective factors is associated with a different attribute of the first surface geometry.

3. The computer-implemented method of clauses 1 or 2, further comprising, executing the modified laser pulse model on the computer-simulated surface to generate a second surface geometry on the computer-simulated surface.

4. The computer-implemented method of any of clauses 1-3, further comprising: determining a quality score for the second surface geometry; based on the quality score for the second surface geometry, performing the global optimization process to generate a third set of values for the set of parameters; and modifying the laser pulse model based on the third set of values to generate another modified laser pulse model.

5. The computer-implemented method of any of clauses 1-4, wherein the quality score includes a plurality of values, and each value included in the plurality of values is associated with a different attribute of the first surface geometry.

6. The computer-implemented method of any of clauses 1-5, wherein the different attributes of the first surface geometry include at least one of a surface profile of the first surface, a surface roughness of the first surface, or an engraving time for generating the first surface.

7. The computer-implemented method of any of clauses 1-6, wherein determining the quality score for the first surface geometry comprises performing a quantitative comparison of the first surface geometry and the target surface geometry.

8. The computer-implemented method of any of clauses 1-7, wherein the quantitative comparison includes at least one of determining a surface quality score of the first surface geometry relative to the target surface geometry, determining an average deviation between the first surface geometry and the target surface geometry, determining a maximum deviation between the first surface geometry and the target surface geometry, determining a surface roughness score of the first surface geometry relative to the target surface geometry, or determining an engraving time score of the first surface geometry.

9. The computer-implemented method of any of clauses 1-8, further comprising generating a plurality of isocontours based on the target surface geometry.

10. The computer-implemented method of any of clauses 1-9, wherein executing the laser pulse model on the computer-simulated surface comprises: directing a plurality of laser pulses towards the computer-simulated surface; and for each laser pulse included in the plurality of laser pulses, determining a modification of the computer-simulated surface caused by the laser pulse.

11. In some embodiments, non-transitory computer readable medium storing instructions that, when executed by a processor, cause the processor to perform the steps of: executing a laser pulse model on a computer-simulated surface to generate a first surface geometry on the computer-simulated surface, wherein the laser pulse model is based on a first set of values for a set of parameters; determining a quality score for the first surface geometry; based on the quality score, performing a global optimization process to generate a second set of values for the set of parameters; and modifying the laser pulse model based on the second set of values to generate a modified laser pulse model.

12. The non-transitory computer readable medium of clause 11 storing instructions that, when executed by the processor, cause the processor to perform the further step of generating a plurality of isocontours based on the target surface geometry.

13. The non-transitory computer readable medium of clauses 11 or 12, wherein executing the laser pulse model on the computer-simulated surface comprises executing the laser pulse model on each isocontour included in the plurality of isocontours.

14. The non-transitory computer readable medium of any of clauses 11-13, wherein executing the laser pulse model on the computer-simulated surface comprises determining a location for one or more laser-raster lines on each isocontour included in the plurality of isocontours.

15. The non-transitory computer readable medium of any of clauses 11-14, wherein executing the laser pulse model on the computer-simulated surface comprises: directing a plurality of laser pulses towards the computer-simulated surface; and for each laser pulse included in the plurality of laser pulses, determining a modification of the computer-simulated surface caused by the laser pulse.

16. The non-transitory computer readable medium of any of clauses 11-15 storing instructions that, when executed by the processor, cause the processor to perform the further step of, for each laser pulse included in the plurality of laser pulses, determining a respective target location on the computer-simulated surface based on target surface geometry.

17. The non-transitory computer readable medium of any of clauses 11-16 storing instructions that, when executed by the processor, cause the processor to perform the further step of determining a location on the computer-simulated surface for one or more laser-raster lines, wherein each laser-raster lines comprises a sequence of laser pulses included in the plurality of laser pulses.

18. The non-transitory computer readable medium of any of clauses 11-17, wherein an objective function of the global optimization process is based on a plurality of objective factors associated with the first surface geometry, and each objective factor included in the plurality of objective factors is associated with a different attribute of the first surface geometry.

19. The non-transitory computer readable medium of any of clauses 11-18 storing instructions that, when executed by the processor, cause the processor to perform the further step of executing the modified laser pulse model on the computer-simulated surface to generate a second surface geometry on the computer-simulated surface.

20. A system, comprising: a memory that stores instructions; and a processor that is communicatively coupled to the memory and is configured to, when executing the instructions, perform the steps of: executing a laser pulse model on a computer-simulated surface to generate a first surface geometry on the computer-simulated surface, wherein the laser pulse model is based on a first set of values for a set of parameters; determining a quality score for the first surface geometry; based on the quality score, performing a global optimization process to generate a second set of values for the set of parameters; and modifying the laser pulse model based on the second set of values to generate a modified laser pulse model.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for determining one or more parameter values for a laser-engraving process, the method comprising:
executing a laser pulse model on a computer-simulated surface to generate a first surface geometry on the computer-simulated surface, wherein the laser pulse model is based on a first set of values for a set of parameters;
determining a quality score for the first surface geometry;
based on the quality score, performing a global optimization process to generate a second set of values for the set of parameters; and
modifying the laser pulse model based on the second set of values to generate a modified laser pulse model.

2. The computer-implemented method of claim 1, wherein an objective function of the global optimization process is based on a plurality of objective factors associated with the first surface geometry, and each objective factor included in the plurality of objective factors is associated with a different attribute of the first surface geometry.

3. The computer-implemented method of claim 1, further comprising, executing the modified laser pulse model on the computer-simulated surface to generate a second surface geometry on the computer-simulated surface.

4. The computer-implemented method of claim 3, further comprising:
determining a quality score for the second surface geometry;
based on the quality score for the second surface geometry, performing the global optimization process to generate a third set of values for the set of parameters; and
modifying the laser pulse model based on the third set of values to generate another modified laser pulse model.

5. The computer-implemented method of claim 1, wherein the quality score includes a plurality of values, and each value included in the plurality of values is associated with a different attribute of the first surface geometry.

6. The computer-implemented method of claim 5, wherein the different attributes of the first surface geometry include at least one of a surface profile of the first surface, a surface roughness of the first surface, or an engraving time for generating the first surface.

7. The computer-implemented method of claim 1, wherein determining the quality score for the first surface geometry comprises performing a quantitative comparison of the first surface geometry and the target surface geometry.

8. The computer-implemented method of claim 7, wherein the quantitative comparison includes at least one of determining a surface quality score of the first surface geometry relative to the target surface geometry, determining an average deviation between the first surface geometry and the target surface geometry, determining a maximum deviation between the first surface geometry and the target surface geometry, determining a surface roughness score of the first surface geometry relative to the target surface geometry, or determining an engraving time score of the first surface geometry.

9. The computer-implemented method of claim 1, further comprising generating a plurality of isocontours based on the target surface geometry.

10. The computer-implemented method of claim 1, wherein executing the laser pulse model on the computer-simulated surface comprises:
directing a plurality of laser pulses towards the computer-simulated surface; and
for each laser pulse included in the plurality of laser pulses, determining a modification of the computer-simulated surface caused by the laser pulse.

11. A non-transitory computer readable medium storing instructions that, when executed by a processor, cause the processor to perform the steps of:
executing a laser pulse model on a computer-simulated surface to generate a first surface geometry on the computer-simulated surface, wherein the laser pulse model is based on a first set of values for a set of parameters;
determining a quality score for the first surface geometry;
based on the quality score, performing a global optimization process to generate a second set of values for the set of parameters; and
modifying the laser pulse model based on the second set of values to generate a modified laser pulse model.

12. The non-transitory computer readable medium of claim 11 storing instructions that, when executed by the processor, cause the processor to perform the further step of generating a plurality of isocontours based on the target surface geometry.

13. The non-transitory computer readable medium of claim 12, wherein executing the laser pulse model on the computer-simulated surface comprises executing the laser pulse model on each isocontour included in the plurality of isocontours.

14. The non-transitory computer readable medium of claim 12, wherein executing the laser pulse model on the computer-simulated surface comprises determining a location for one or more laser-raster lines on each isocontour included in the plurality of isocontours.

15. The non-transitory computer readable medium of claim 11, wherein executing the laser pulse model on the computer-simulated surface comprises:
directing a plurality of laser pulses towards the computer-simulated surface; and
for each laser pulse included in the plurality of laser pulses, determining a modification of the computer-simulated surface caused by the laser pulse.

16. The non-transitory computer readable medium of claim 15 storing instructions that, when executed by the processor, cause the processor to perform the further step of, for each laser pulse included in the plurality of laser pulses, determining a respective target location on the computer-simulated surface based on target surface geometry.

17. The non-transitory computer readable medium of claim 15 storing instructions that, when executed by the processor, cause the processor to perform the further step of determining a location on the computer-simulated surface for one or more laser-raster lines, wherein each laser-raster lines comprises a sequence of laser pulses included in the plurality of laser pulses.

18. The non-transitory computer readable medium of claim 11, wherein an objective function of the global optimization process is based on a plurality of objective factors associated with the first surface geometry, and each objective factor included in the plurality of objective factors is associated with a different attribute of the first surface geometry.

19. The non-transitory computer readable medium of claim 11 storing instructions that, when executed by the processor, cause the processor to perform the further step of executing the modified laser pulse model on the computer-simulated surface to generate a second surface geometry on the computer-simulated surface.

20. A system, comprising:
a memory that stores instructions; and
a processor that is communicatively coupled to the memory and is configured to, when executing the instructions, perform the steps of:
executing a laser pulse model on a computer-simulated surface to generate a first surface geometry on the computer-simulated surface, wherein the laser pulse model is based on a first set of values for a set of parameters;
determining a quality score for the first surface geometry;
based on the quality score, performing a global optimization process to generate a second set of values for the set of parameters; and
modifying the laser pulse model based on the second set of values to generate a modified laser pulse model.
